(19) United States
(12) Patent Application Publication
(10) Pub. No.: US 2025/0241213 A1
(43) Pub. Date: Jul. 24, 2025

(54) SEMICONDUCTOR DEVICE INCLUDING PLUG ELECTRODE WITH NANORODS AND METHOD OF MANUFACTURING THE SAME

(71) Applicant: SK hynix Inc., Icheon-si (KR)

(72) Inventor: Young Jae KWON, Icheon-si (KR)

(21) Appl. No.: 18/736,360

(22) Filed: Jun. 6, 2024

(30) Foreign Application Priority Data
Jan. 19, 2024 (KR) 10-2024-0009058

(51) Int. Cl. H10N 70/00; H10B 63/00; H10N 70/20

(52) U.S. Cl. CPC H10N 70/8833; H10B 63/30; H10N 70/063; H10N 70/066; H10N 70/24; H10N 70/841; H10N 70/023

(57) ABSTRACT

A semiconductor device according to an embodiment of the present disclosure includes a lower electrode, a plug electrode disposed over the lower electrode and including a plurality of conductive nanorods, a resistance change layer disposed over the plug electrode, and an upper electrode disposed over the resistance change layer.

### CROSS-REFERENCE TO RELATED APPLICATION

The present application claims priority under 35 U.S.C. § 119(a) to Korean Application No. 10-2024-0009058, filed on Jan. 19, 2024, which is incorporated herein by reference in its entirety.

### BACKGROUND

### 1. Technical Field

The present disclosure generally relates to a semiconductor device including a plug electrode and, more particularly, to a semiconductor device including a plug electrode with a plurality of nanorods and a method of manufacturing the same.

### 2. Related Art

In general, a resistance change material may refer to a material whose electrical resistance changes when an external stimulus such as heat, current, voltage, light, etc. is applied. The resistance change material can maintain the changed electrical resistance even after the external stimulus is removed. A resistance change memory device utilizes the electrical characteristics of the above-mentioned resistance change material to store signal information. A resistance change memory device may switch the resistance state of the resistance change material between a low resistance state and a high resistance state through a set operation and a reset operation.

A resistance change memory device may be classified as a resistive RAM device, a phase change RAM device, a magnetic RAM device, etc. depending on the basis for the switching operation. Among resistance change memory devices, the resistive RAM device can implement a plurality of differentiated resistance states through a method of generating or removing electrical paths with varying conductivity within the resistance change layer by applying voltage or current to both ends of the resistance change layer.

### SUMMARY

A semiconductor device according to an embodiment of the present disclosure may include a lower electrode, a plug electrode disposed over the lower electrode and including a plurality of conductive nanorods, a resistance change layer disposed over the plug electrode, and an upper electrode disposed over the resistance change layer.

There is disclosed a method of manufacturing a semiconductor device. In the method, a lower electrode may be formed over a substrate. An interlayer insulation layer including a hole pattern may be formed over the lower electrode. A plug electrode including a plurality of conductive nanorods and a non-conductive mold layer surrounding the plurality of conductive nanorods may be formed in the hole pattern. A resistance change material layer and an upper electrode material layer may be sequentially formed over the interlayer insulation layer including the plug electrode. The resistance change material layer and the upper electrode material layer may be patterned over the interlayer insulation layer to form a resistance change layer that covers the plug electrode and an upper electrode.

### BRIEF DESCRIPTION OF THE DRAWINGS

FIG. 1 is a cross-sectional view schematically illustrating a semiconductor device according to an embodiment of the present disclosure.

FIG. 2 is a view illustrating a plug electrode of FIG. 1 cut along a line I-I′ and shown on the x-y plane.

FIG. 3 is a view illustrating a contact surface between the plug electrode and a resistance change layer of FIG. 1 cut along a line II-II′ and shown on the x-y plane.

FIGS. 4 and 5 are views schematically illustrating an operation method of a semiconductor device according to an embodiment of the present disclosure.

FIG. 6 is a cross-sectional view schematically illustrating a semiconductor device according to another embodiment of the present disclosure.

FIG. 7A is a cross-sectional view schematically illustrating a semiconductor device according to yet another embodiment of the present disclosure.

FIG. 7B is a view illustrating a plug electrode of FIG. 7A cut along a line III-III′ and shown on the x-y plane.

FIGS. 8 to 15 are cross-sectional views schematically illustrating a method of manufacturing a semiconductor device according to an embodiment of the present disclosure.

FIGS. 16, 17A, 17B, 18, and 19 are cross-sectional views schematically illustrating a method of manufacturing a semiconductor device according to another embodiment of the present disclosure.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, and “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

Terms used in the specification of the present application are terms selected in consideration of functions in the presented embodiments, and the meaning of the terms may vary depending on the intention or customs of a user or operator in the technical field. The meanings of the terms used follow the definitions defined when specifically defined herein, and may be interpreted as meanings generally recognized by those skilled in the art in the absence of specific definitions.

Embodiments of the present disclosure may be described through drawings using an x-y-z coordinate system. The x-direction referred to in this specification may mean a direction parallel to the x-axis. Similarly, the y-direction and the z-direction may refer to directions parallel to the y-axis and z-axis, respectively.

In addition, in describing a method or a manufacturing method, each process constituting the method may proceed in a different order from the specified order unless a specific order is clearly described in context. That is, each process may proceed in the same order as specified, may proceed substantially concurrently, or may proceed in the opposite order.

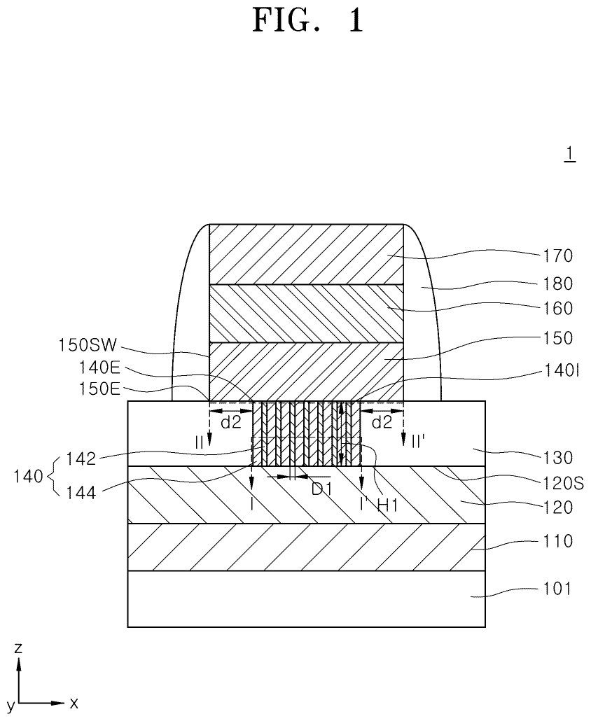

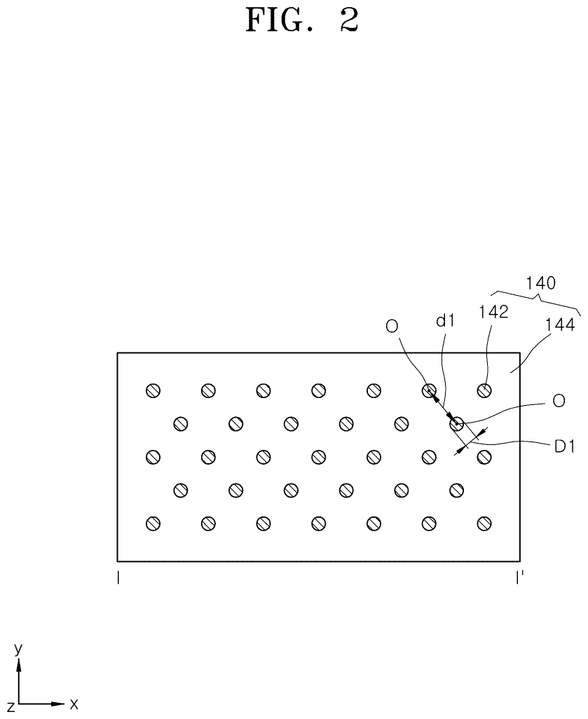

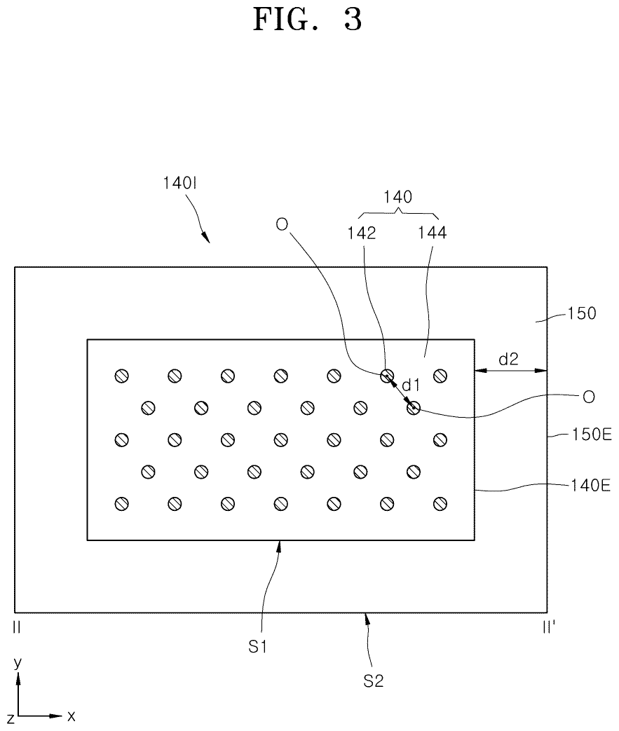

FIG. 1 is a cross-sectional view schematically illustrating a semiconductor device according to an embodiment of the present disclosure. FIG. 2 is a view illustrating a plug electrode of FIG. 1 cut along a line I-I′ and shown on the x-y plane. FIG. 3 is a view illustrating a contact surface between the plug electrode 140 and a resistance change layer of FIG. 1 cut along a line II-II′ and shown on the x-y plane.

Referring to FIGS. 1 to 3, a semiconductor device 1 may include a lower electrode 120, a plug electrode 140 disposed over the lower electrode 120, a resistance change layer 150 disposed over the plug electrode 140, an oxygen vacancy reservoir 160 disposed over the resistance change layer 150, and an upper electrode 170 disposed over the oxygen reservoir 160.

In an embodiment, the semiconductor device 1 may be a resistive RAM device in which the electrical resistance state inside the resistance change layer 150 can reversibly change depending on the magnitude or polarity of a voltage applied between the lower electrode 120 and the upper electrode 170. When the electrical resistance state changes, the resistance change layer 150 may store the altered electrical resistance state in a non-volatile manner after the applied voltage is removed. The semiconductor device 1 may have a plurality of distinct and measurable resistance states, and may also store multi-level signal information corresponding to the plurality of resistance states.

Referring to FIG. 1, a substrate 101 may be provided. The substrate 101 may be made of various materials as long as the material satisfies the conditions for performing a semiconductor integration process. The substrate 101 may include a semiconductor, insulator, or conductor. The substrate 101 may include integrated circuits (not illustrated). The integrated circuits may be circuits that drive or control the semiconductor device 1. As an example, the integrated circuits may include a plurality of field effect transistors.

A first interlayer insulation layer 110 may be disposed on the substrate 101. In FIG. 1, the first interlayer insulation layer 110 may electrically insulate the lower electrode 120 on the first interlayer insulation layer 110 from the substrate 101. The first interlayer insulation layer 110 may include, for example, oxide, nitride, oxynitride, or a combination of two or more thereof.

The lower electrode 120 may be disposed on the first interlayer insulation layer 110. The lower electrode 120 may include at least one layer of conductive material. The conductive material layer may include, for example, a doped semiconductor material, metal, metal nitride, metal carbide, metal silicide, or metal oxide. As an example, the conductive material layer may include n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof. As an example, the lower electrode 120 may be a line-shaped pattern layer extending along one direction.

In some embodiments, at least one conductive layer may be disposed between the substrate 101 and the lower electrode 120. The conductive layer may function as an interconnection electrically connecting a plurality of integrated circuits of the substrate 101 to each other, or an interconnection electrically connecting the integrated circuits and the lower electrode 120 to each other. The conductive layer may be disposed in, on, or under the first interlayer insulation layer 110.

A second interlayer insulation layer 130 may be disposed on the lower electrode 120. The second interlayer insulation layer 130 may include an insulative material. The insulative material may include, for example, silicon oxide, silicon nitride, silicon oxynitride, metal nitride, metal oxide, metal oxynitride, or a combination of two or more thereof. The second interlayer insulation layer 130 may be disposed to surround the plug electrode 140.

The plug electrode 140 may be disposed in the second interlayer insulation layer 130. The plug electrode 140 may include a plurality of conductive nanorods 142 and a non-conductive mold layer 144 surrounding the plurality of nanorods 142. The plurality of conductive nanorods 142 may be physically separated from each other.

In an embodiment, each of the plurality of conductive nanorods 142 may extend along a first direction (e.g., z-direction) perpendicular to a surface 120S of the lower electrode 120. Each of the plurality of conductive nanorods 142 may contact the lower electrode 120 and the resistance change layer 150. As illustrated in FIG. 1, each of the plurality of conductive nanorods 142 may have a pillar-shape having a predetermined width D and a predetermined height H1. As illustrated in FIGS. 2 and 3, each of the plurality of conductive nanorods 142 may have a circular cross-section whose diameter is a predetermined width D1. In some embodiments, each of the plurality of conductive nanorods 142 may have an oval or polygonal cross-section having the predetermined width D1 in a long axis direction. As an example, the predetermined width D1 may be 1 nanometer (nm) to 5 nm.

Referring to FIGS. 1 to 3, the plurality of conductive nanorods 142 may be disposed spaced apart from each other in a second direction (e.g., x-direction or y-direction) perpendicular to the first direction. The plurality of conductive nanorods 142 may be arranged at regular intervals along the second direction. As an example, each of the plurality of conductive nanorods 142 may be spaced apart at a pitch d1 of 1 nm to 50 nm. Here, the pitch d1 of the conductive nanorods 142 may mean the distance between the centers O of different adjacent conductive nanorods 142. As another example, the pitch d1 may be a multiple of a nanorod dimension such as 1 to 10 times the predetermined width D1.

Each of the plurality of conductive nanorods 142 may include a conductive material. The conductive material may include, for example, a doped semiconductor material, metal, metal nitride, metal carbide, metal silicide, or metal oxide. As an example, the conductive material may include n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

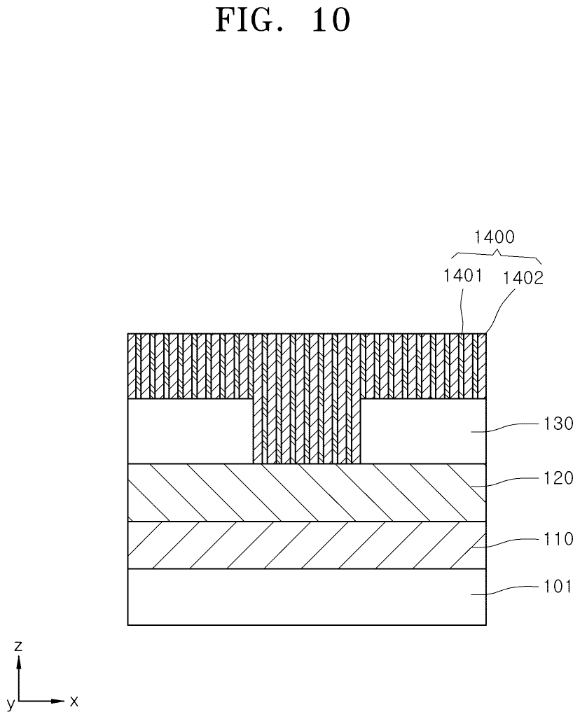

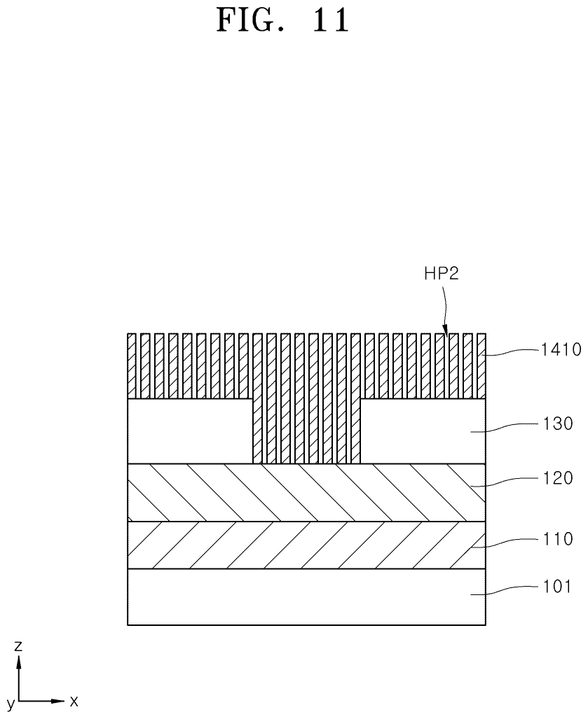

The non-conductive mold layer 144 may include a polymer material. The non-conductive mold layer 144 may electrically insulate the plurality of conductive nanorods 142 from each other. In an embodiment, the non-conductive mold layer 144 may be formed from one of different polymer blocks (1401 and 1402 in FIG. 10) that are phase-separated from a block copolymer film (1400 in FIG. 10), in a manufacturing method described below in connection with FIGS. 10 and 11.

Referring back to FIG. 1, the resistance change layer 150 may be disposed on the second interlayer insulation layer 130 and the plug electrode 140. The resistance change layer 150 may include a resistance change material whose electrical resistance state changes depending on the application of an external voltage. For example, the resistance change material may include metal oxide such as titanium oxide, aluminum oxide, nickel oxide, copper oxide, zirconium oxide, manganese oxide, hafnium oxide, tungsten oxide, tantalum oxide, niobium oxide, and iron oxide. The metal oxide may include oxygen vacancies.

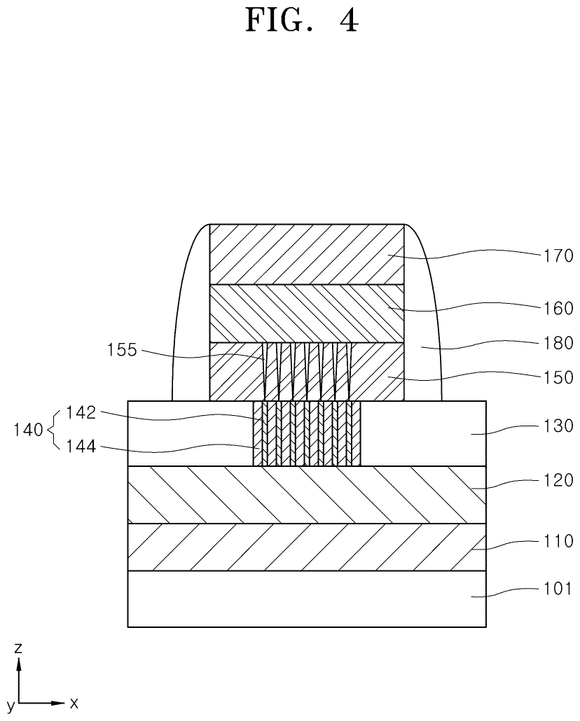

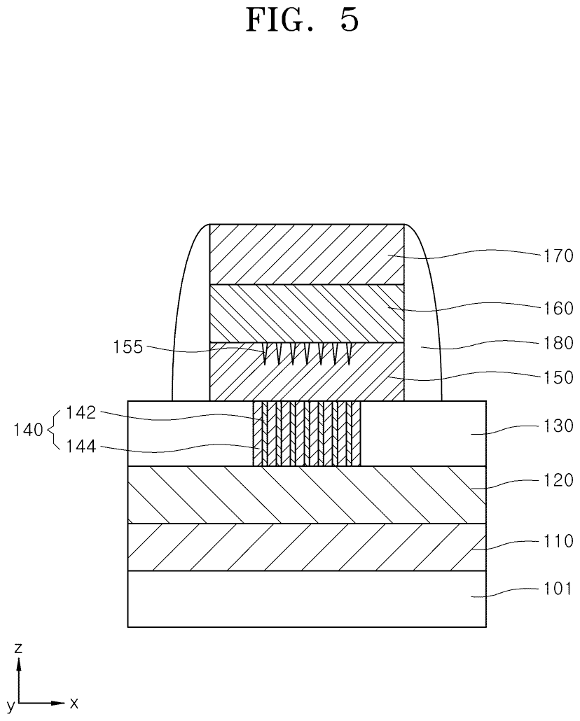

In an embodiment, as will be described later with reference to FIGS. 4 and 5, the resistance change layer 150 may include a plurality of conductive filaments (155 in FIGS. 4 and 5) internally generated through the application of an external voltage. Each of the plurality of conductive filaments 155 may be connected to a corresponding conductive nanorod among the plurality of conductive nanorods 142. The plurality of conductive filaments 155 may include oxygen vacancies. The width of the plurality of conductive filaments 155 can be controlled by controlling the width D1 of the plurality of conductive nanorods 142 as described above.

Referring to FIGS. 1 and 3, the plug electrode 140 and the resistance change layer 150 may be disposed to contact each other. As illustrated in FIG. 3, in a plane 140I where the interface between the plug electrode 140 and the resistance change layer 150 is located, a cross-sectional region S1 of the plug electrode 140 may be located within a cross-sectional region S2 of the resistance change layer 150. That is, in the plane 140I, the entire cross-sectional region S1 of the plug electrode 140 may overlap a portion of the cross-sectional region S2 of the resistance change layer 150. Accordingly, in the plane 140I, the area of the cross-sectional region S1 of the plug electrode 140 may be smaller than the area of the cross-sectional region S2 of the resistance change layer 150. In addition, in the plane 140I where the interface between the plug electrode 140 and the resistance change layer 150 is located, a cross-sectional region of the plurality of conductive nanorods 142 may be located within the cross-sectional region S2 of the resistance change layer 150.

In an embodiment, in the plane 140I where the interface between the plug electrode 140 and the resistance change layer 150 is located, a pattern edge 140E of the plug electrode 140 may be located spaced apart from a pattern edge 150E of the adjacent resistance change layer 150 by a predetermined distance. As an example, the separation distance d2 between the pattern edges 140E and 150E may be 5 nm or more. Accordingly, the plurality of conductive nanorods 142, which are located away from the pattern edge 140E, may be located at a distance of 5 nm or more from the pattern edge 150E of the adjacent resistance change layer 150.

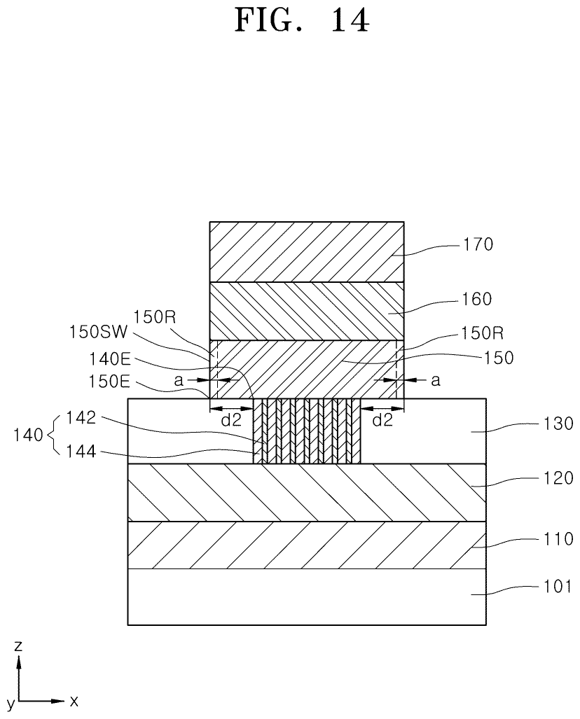

As will be described with reference to FIG. 14, a region of the resistance change layer 150, located at a distance of less than 5 nm from the pattern edge 150E of the resistance change layer 150, may correspond to an etching damage region (150R in FIG. 14). When at least a portion of the etching damage region 150R overlaps the plug electrode 140 in the z-direction, leakage current may flow through the etching damage region 150R between the plug electrode 140 and the upper electrode 170, which may deteriorate the electrical reliability of a semiconductor device. According to embodiments of the present disclosure, however, the etching damage region 150R of the resistance change layer 150 and the plug electrode 140 do not overlap each other in the z-direction. Accordingly, the leakage current characteristics of the semiconductor device 1 can be improved.

Referring back to FIG. 1, the oxygen vacancy reservoir 160 may be disposed on the resistance layer 150. The oxygen vacancy reservoir 160 may have electrical conductivity. In an embodiment, the oxygen vacancy reservoir 160 may include a metal that is highly reactive with oxygen. For example, the oxygen vacancy reservoir 160 may include tantalum (Ta), titanium (Ti), or a combination thereof. For example, the oxygen vacancy reservoir 160 may include, for example, tantalum nitride, titanium nitride, or a combination thereof.

When a set voltage is applied, the oxygen vacancy reservoir 160 may receive oxygen ions from the resistance change layer 150, which results in oxygen vacancies in the resistance change layer 150. As will be described later, the oxygen vacancies generated inside the resistance change layer 150 may be arranged along the electric field formed by the set voltage, thereby forming the conductive filaments.

Referring to FIG. 1, the upper electrode 170 may be disposed on the oxygen vacancy reservoir 160. The upper electrode 170 may include at least one layer of a conductive material. The conductive material layer may include, for example, a doped semiconductor material, metal, metal nitride, metal carbide, metal silicide, or metal oxide. As an example, the conductive material layer may include n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

Referring to FIG. 1, a spacer 180 may be disposed on side walls of the resistance change layer 150, the oxygen vacancy reservoir 160, and the upper electrode 170 and over the second interlayer insulation layer 130. The spacer 180 may function as a barrier layer that electrically insulates the resistance change layer 150, the oxygen vacancy reservoir 160, and the upper electrode 170 in the lateral direction and protects the resistance change layer 150, the oxygen vacancy reservoir 160, and the upper electrode 170 from material diffusion. The spacer 180 may include an insulative material, for example, oxide, nitride, oxynitride, or a combination of two or more thereof.

As described above, semiconductor devices according to embodiments of the present disclosure may include a plug electrode including a plurality of nanorods that are physically separated from each other. The width of each of the plurality of conductive nanorods can be controlled. By controlling the width of each of the conductive nanorods, the width of each of the conductive filaments generated within the resistance change layer and connected to the conductive nanorods can be controlled. Through this, as will be described later with reference to FIGS. 4 and 5, the reliability of a write operation to store signal information using the plurality of conductive filaments can be improved.

In semiconductor devices according to embodiments of the present disclosure, in the plane where the interface between the plug electrode 140 and the resistance change layer 150 is located, the cross-sectional region of the plug electrode may be located within the cross-sectional region of the resistance change layer. Through this, the plug electrode can be arranged so it does not overlap the etching damage region in the pattern edge of the resistance change layer 150. As a result, leakage current can be prevented from passing through the etching damage region.

FIGS. 4 and 5 are views schematically illustrating an operation method of a semiconductor device according to an embodiment of the present disclosure. Methods of operating a semiconductor device of FIGS. 4 and 5 may be described using a semiconductor device 1 described above with reference to FIGS. 1 to 3. In an embodiment, the semiconductor device 1 may be a resistive RAM device whose electrical resistance state is depends on whether conductive filaments are formed inside a resistance change layer 150.

FIG. 4 is a view schematically illustrating a set operation, in which the electrical resistance state of the resistance change layer 150 switches from a high resistance state to a low resistance state. FIG. 5 is a view schematically illustrating a reset operation, in which the electrical resistance state of the resistance change layer 150 switches from a low resistance state to a high resistance state.

Referring to FIG. 4, a set voltage may be applied between a lower electrode 120 and an upper electrode 170. A method of applying the set voltage may include applying a bias with a positive polarity to the upper electrode 170 and applying a bias with a negative polarity or a ground bias to the lower electrode 120.

By applying the set voltage, oxygen vacancies may be provided from an oxygen vacancy reservoir 160 to the resistance change layer 150. Accordingly, the concentration of oxygen vacancies may increase from a region of the resistance change layer 150 adjacent to the oxygen vacancy reservoir 160 to an inner region of the resistance change layer 150. Subsequently, as the oxygen vacancies are arranged along the electric field formed by the set voltage, a plurality of conductive filaments 155 may grow into the resistance change layer 150 from the interface between the oxygen vacancy reservoir 160 and the resistance change layer 150. The plurality of grown conductive filaments 155 may electrically connect a plug electrode 140 to the oxygen vacancy reservoir 160, so that the electrical resistance state of the resistance change layer 150 may be converted from a high resistance state to a low resistance state.

Referring to FIG. 4, when the plug electrode 140 includes a plurality of conductive nanorods 142 that are electrically separated from each other, the plurality of conductive filaments 155 may be respectively connected to the plurality of conductive nanorods 142. As an example, when the set voltage is applied, the electric field may be concentrated on the plurality of conductive nanorods 142 instead of a non-conductive mold layer 144 in the plug electrode 140. As a result, the conductive filaments 155 grown in the resistance change layer 150 may be connected to the conductive nanorods 142 in a 1:1 correspondence. Meanwhile, the electric field is not concentrated on the non-conductive mold layer 144 within the plug electrode 142. Accordingly, the conductive filament 155 might not be connected to the non-conductive mold layer 144, and the growth of the conductive filaments 155 in the lateral direction (e.g., x-direction or y-direction) after being connected to the conductive nanorods 142 may be restricted or suppressed. As a result, each of the conductive filaments 155 respectively connected to the conductive nanorods 142 may have a controlled width.

In addition, the number of the conductive filaments 155 connected to the conductive nanorods 142 may vary depending on the magnitude of the set voltage. As an example, as the magnitude of the set voltage increases, the number of the conductive filaments 155 connected to the conductive nanorods 142 may increase. The electrical resistance of the resistance change layer 150 may decrease linearly in proportion to the number of the conductive filaments 155 connected to the conductive nanorods 142. Accordingly, by controlling the magnitude of the set voltage, a plurality of electrical resistance states of the resistance change layer 150 can be linearly controlled.

In FIG. 4, the conductive filaments 155 are illustrated as respectively connected to all of the plurality of conductive nanorods 142, but the present disclosure might not necessarily be limited thereto. In some embodiments, the conductive filaments 155 may be connected to some from among all of the plurality of conductive nanorods 142, and the conductive filaments 155 might not be connected to other conductive nanorods 142. Although not all conductive nanorods 142 are connected to a conductive filament 155, those that are connected are connected in a 1:1 correspondence.

In an embodiment, and referring to FIGS. 2 and 3, at the contact portion between the conductive nanorod 142 and the conductive filament 155, the width of the conductive filament 155 may be less than ½ of the pitch d1 between the conductive nanorods 142. Accordingly, the conductive filaments 155 respectively connected to adjacent conductive nanorods 142 can be prevented from contacting each other in a lateral direction.

In an embodiment, the width or cross-sectional area of the conductive filament 155 may be equal to or smaller than the width D1 or the cross-sectional area π*(D1/2)² of the conductive nanorod 142 (see FIGS. 1 and 2). In another embodiment, at the contact portion, the width or cross-sectional area of the conductive filament 155 may be larger than the width D1 or cross-sectional area π*(D1/2)² of the conductive nanorod 142. However, even in this case, the width of the conductive filament 155 may be smaller than ½ of the pitch d1 between the conductive nanorods 142 to avoid lateral contact.

As described above, according to embodiments of the present disclosure, a plug electrode 140 may include a plurality of conductive nanorods 142 separated from each other, and may generate conductive filaments 155 respectively connected to the plurality of conductive nanorods 142. The number of the conductive filaments 155 respectively connected to the plurality of conductive nanorods 142 can be controlled by controlling the magnitude of the set voltage. As a result, the electrical resistance state of the resistance change layer 150 can be controlled in linear proportion to the number of the conductive filaments 155 connected to the conductive nanorods 142.

Further, in embodiments of the present disclosure, because the plug electrode 140 includes the plurality of conductive nanorods 142 that are separated from each other, when the set voltage is applied, an electric field can be focused on plurality of conductive nanorods 142 of the plug electrode 140. Thus, compared to conventional cases in which the plug electrode 140 includes a single electrode pattern that is not separated from each other, filament formation can be initiated at a relatively low set voltage, and the conductive filaments 155 with relatively small widths can be generated. Because filament formation initiates at a relatively low set voltage, it may be easy to adjust the width of the conductive filaments 155 according to the applied set voltage. As a result, the number of electrical resistance states that can be implemented can be increased in proportion to the margin of change in the widths of the conductive filaments 155. Additionally, it is possible to generate a higher resistance state by forming a smaller number of conductive filaments 155 through the adjustment of the set voltage. Therefore, multi-level signals can be effectively implemented using the plurality of conductive filaments 155 separated from each other. In addition, even when some of the plurality of conductive filaments 155 are disconnected due to malfunction during the set operation, the remaining conductive filaments 155 remain connected to the conductive nanorods 142. Accordingly, the number of set defects can be reduced, compared to conventional cases using a single or mono electrode pattern.

Referring to FIG. 5, a reset voltage may be applied between a lower electrode 120 and an upper electrode 170. As an example, the method of applying the reset voltage may be performed by applying a bias with a negative polarity to the upper electrode 170 and applying a bias with a positive polarity or a ground bias to the lower electrode 120.

The plurality of conductive filaments 155 can be disconnected by the reset voltage. The reset voltage cause partial decomposition of the plurality of conductive filaments 155 respectively, and discharge of the oxygen vacancies from the conductive filaments 155 into the resistance change layer 150. In addition, the reset voltage may move the oxygen vacancies inside the resistance change layer 150 into the oxygen vacancy reservoir layer 160. The disconnection of the plurality of conductive filaments 155 may begin or originate from the contact portions between the conductive filaments 155 and the conductive nanorods 142.

As described above, compared to conventional electrodes, a resistance change layer 150 according to embodiments of the present disclosure may include a plurality of conductive filaments 155 each having a reduced width and arranged at a predetermined interval. Each of the plurality of conductive filaments 155 may have a reduced width compared to a conventional case, so that the conductive filaments can be disconnected with a relatively low reset voltage, compared to the conventional case, which requires a higher voltage to disconnect a single conductive filament with a relatively large width. Accordingly, the reliability of the reset operation of the semiconductor device 1 can be improved.

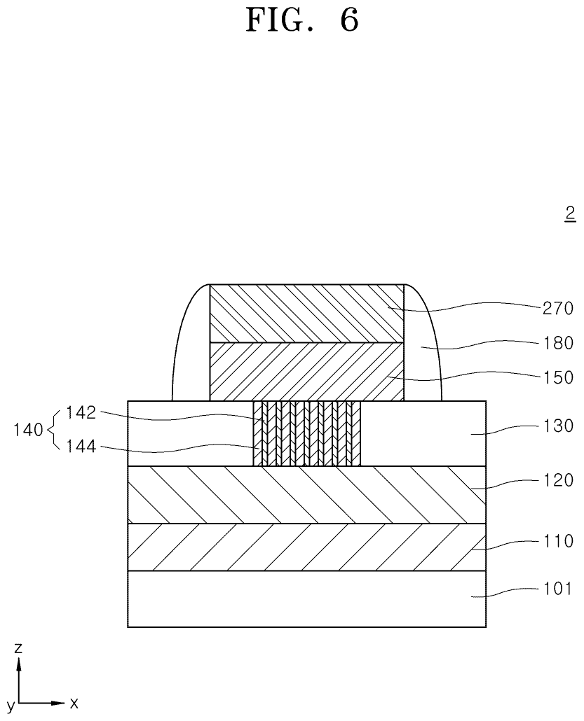

FIG. 6 is a cross-sectional view schematically illustrating a semiconductor device according to another embodiment of the present disclosure. A semiconductor device 2 of FIG. 6 does not include an oxygen vacancy reservoir compared to a semiconductor device 1 of FIG. 1.

Referring to FIG. 6, the oxygen vacancy reservoir may be excluded, so that an upper electrode 270 may be directly disposed on a resistance change layer 150. The upper electrode 270 may also function as an oxygen vacancy reservoir. The upper electrode 270 may include a metal having high reactivity with oxygen. For example, the upper electrode 270 may include tantalum (Ta), titanium (Ti), or a combination thereof. In an embodiment, the upper electrode 270 may include, for example, tantalum nitride, titanium nitride, or a combination thereof.

When a set voltage is applied to the upper electrode 270, an electric field is formed in the resistance change layer 150. As some of oxygen ions of the resistance change layer 150 move to the upper electrode 270 due to the electric field, oxygen vacancies may be formed in the resistance change layer 150. The oxygen vacancies may be arranged to form conductive filaments along an electric field formed by the set voltage.

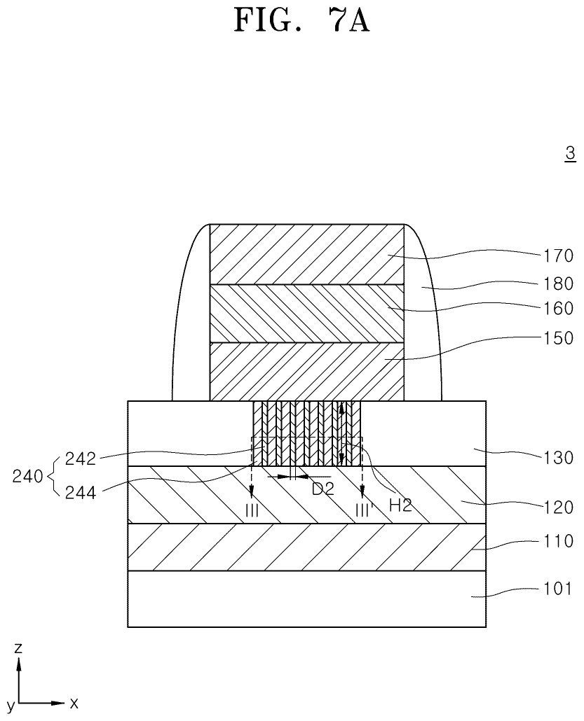

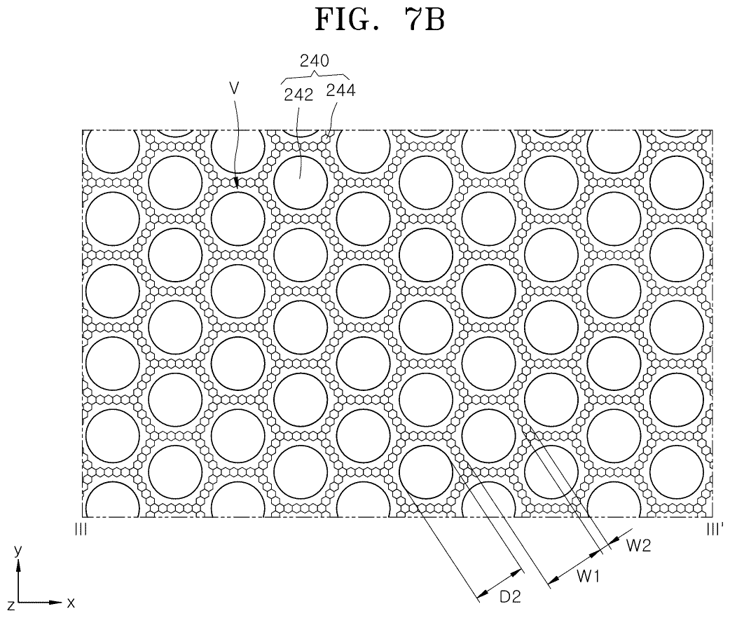

FIG. 7A is a cross-sectional view schematically illustrating a semiconductor device according to yet another embodiment of the present disclosure. FIG. 7B is a view illustrating a plug electrode of FIG. 7A cut along a line III-III′ and shown on the x-y plane.

Referring to FIGS. 7A and 7B, a semiconductor device 3 may have a plug electrode 240 with a different configuration when compared to the plug electrode of a semiconductor device 1 of FIG. 1. The plug electrode 240 may include a plurality of conductive nanorods 242 and a non-conductive mold layer 244 surrounding the plurality of conductive nanorods 242. The configuration of the plurality of conductive nanorods 242 may be substantially the same as the configuration of the plurality of conductive nanorods 142 described above with reference to FIG. 1. The non-conductive mold layer 244 may be a metal-organic framework layer 244.

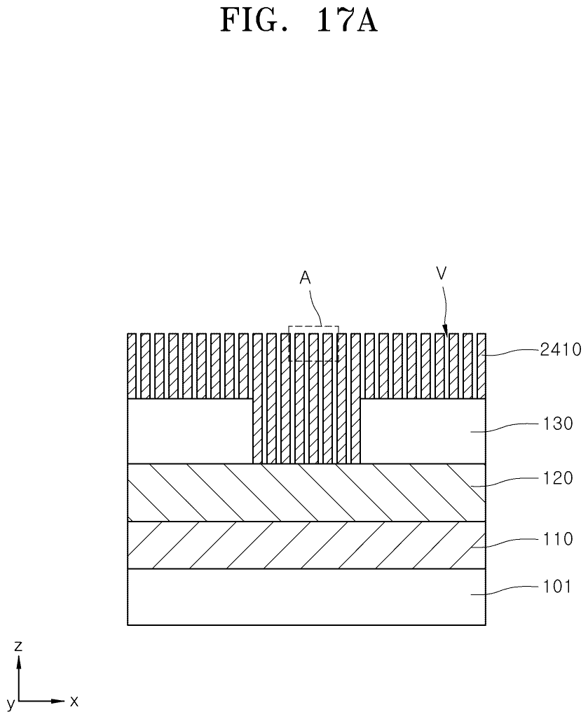

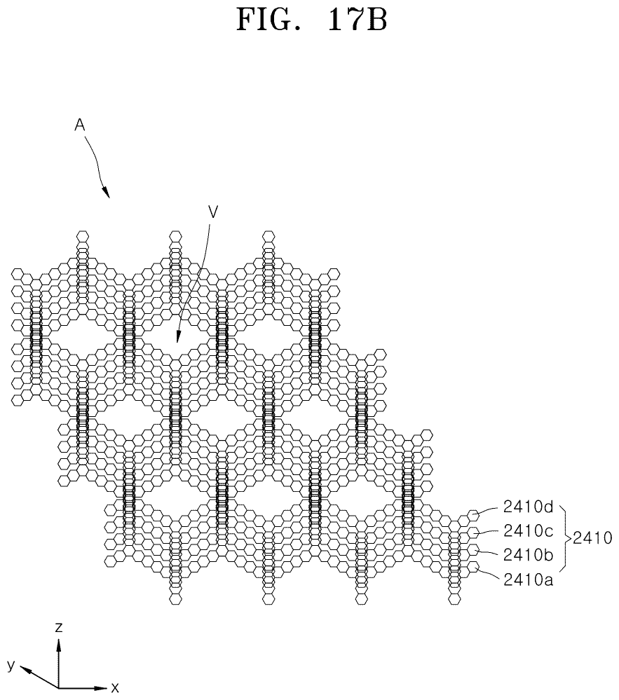

In an embodiment, the metal-organic framework layer 244 may be a thin film structure formed by sequentially stacking two-dimensional metal-organic frameworks that each have a cavity V. The two-dimensional metal-organic framework may refer to a metal-organic framework having a single layer structure in the form of a sheet with a thickness of several nanometers or less. As will be described later in connection with FIGS. 17A and 17B, a plurality of two-dimensional metal-organic frameworks 2410a, 2410b, 2410c, and 2410d may be stacked in the z-direction such that the cavities V of the plurality of two-dimensional metal-organic structures 2410a, 2410b, 2410c, and 2410d overlap each other. Accordingly, the metal-organic framework layer 2410 illustrated in FIG. 17B may have a channel of the cavities V extending in the z-direction.

Referring to FIGS. 7A and 7B, the plurality of conductive nanorods 242 may be disposed in channels formed by the cavities V of the metal-organic framework layer 244. The plurality of conductive nanorods 242 and the channel of the cavities V may both extend in the z-direction. A width D2 of each of the plurality of conductive nanorods 242 may be equal to or smaller than a width w1 of the cavities V. In an embodiment, the width w1 of a cavity V may be 10 nm to 100 nm. In an embodiment, the interval w2 between the cavities V may be 1/10 of the width w1 to the width w1 of the cavity V.

As described above, according to embodiments of the present disclosure, a plurality of conductive nanorods 242 included in a plug electrode 240 may be effectively implemented by using a metal-organic framework layer 244 having a channel of the cavities V arranged at regular intervals, with the plurality of conductive nanorods 242 arranged within the cavities V, respectively.

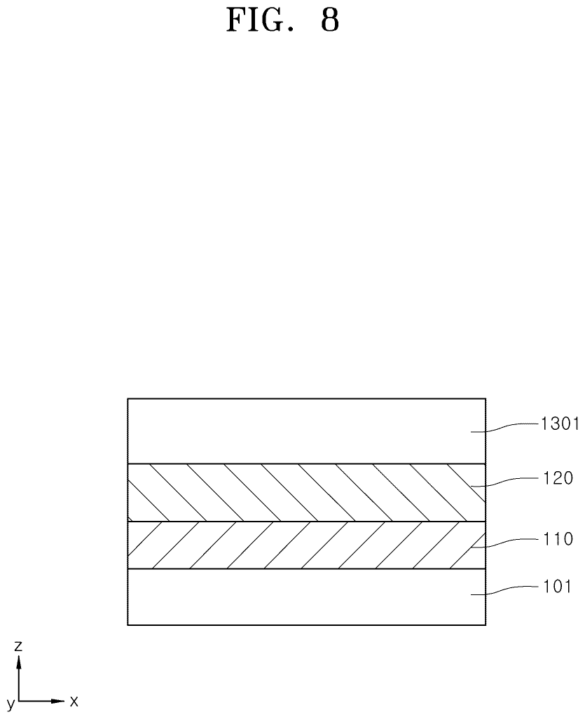

FIGS. 8 to 15 are cross-sectional views schematically illustrating a method of manufacturing a semiconductor device according to an embodiment of the present disclosure. In an embodiment, the method of manufacturing the semiconductor device may be applied to a method of manufacturing a semiconductor device 1 described above with reference to FIGS. 1 to 3 or to a method of manufacturing a semiconductor device 2 described above with reference to FIG. 6.

Referring to FIG. 8, a substrate 101 may be provided. The substrate 101 may be made of various materials as long as the materials satisfies the conditions for performing a semiconductor integration process. The substrate 101 may include integrated circuits. The integrated circuits may be circuits that drive or control the semiconductor device 1.

A first interlayer insulation layer 110 may be formed on the substrate 101. The first interlayer insulation layer 110 may include, for example, oxide, nitride, oxynitride, or a combination of two or more thereof. A lower electrode 120 may be formed on the first interlayer insulation layer 110. The lower electrode 120 may include at least one layer of conductive material layer. The conductive material layer may include, for example, a doped semiconductor material, metal, metal nitride, metal carbide, metal silicide, or metal oxide.

In some embodiments, at least one conductive layer may be disposed between the substrate 101 and the lower electrode 120. The conductive layer may function as an interconnection electrically connecting a plurality of integrated circuits (not illustrated) of the substrate 101 or an interconnection electrically connecting the integrated circuits to the lower electrode 120.

Next, an insulative material layer 1301 may be formed on the lower electrode 120. The insulative material layer 1301 may include, for example, oxide, nitride, oxynitride, or a combination of two or more thereof.

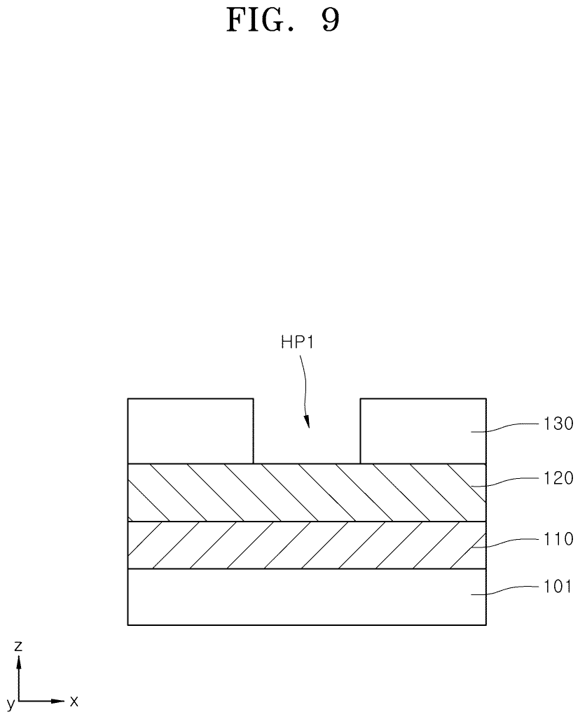

Referring to FIG. 9, the insulative material layer (1301 in FIG. 8) may be patterned to form a hole pattern HP1. In an embodiment, the hole pattern HP1 may expose the lower electrode 120. The hole pattern HP1 may have a circular, oval, or polygonal cross-sectional shape, but other embodiments are not limited to these examples. The insulative material layer 1301 may be patterned and converted into a second interlayer insulation layer 130 having the hole pattern HP1.

Referring to FIG. 10, a block copolymer layer 1400 filling the hole pattern HP1 and disposed on the second interlayer insulation layer 130 outside the hole pattern HP1 may be formed. The block copolymer layer 1400 may include a polymer material in which first and second polymer blocks having different properties are linked by covalent bonds. As an example, one of the first and second polymer blocks may exhibit hydrophilicity, and the other may exhibit hydrophobicity. As another example, one of the first and second polymer blocks may exhibit a relatively strong polarity, and the other may exhibit a relatively weak polarity or non-polarity.

The block copolymer layer 1400 may be formed by dissolving the polymers of the first and second polymer blocks in a solvent and spin-coating the dissolved polymers of the first and second polymer blocks, for example. The solvent may be removed by evaporation after coating. The first and second polymer blocks may be randomly mixed with each other within the block copolymer layer 1400.

Next, the block copolymer layer 1400 may be heat-treated at a temperature equal to or higher than the glass transition temperature of the polymers of the first and second polymer blocks. As a result, the block copolymer layer 1400 may be phase-separated into a first polymer block 1401 having a cylindrical shape and a second polymer block 1402 surrounding the first polymer block 1401.

Referring to FIG. 11, the first polymer block 1401 may be selectively removed to form a polymer mold layer 1410 having a plurality of through holes HP2. The polymer mold layer 1410 may include the second polymer block 1402 of FIG. 10. In an embodiment, the first polymer block 1401 may be selectively removed by an etching process using the etch selectivity between the first and second polymer blocks 1401 and 1402. The etching process may include wet development or dry development. In another embodiment, the first polymer block 1401 may be selectively removed using a plasma treatment method or a radiation irradiation method.

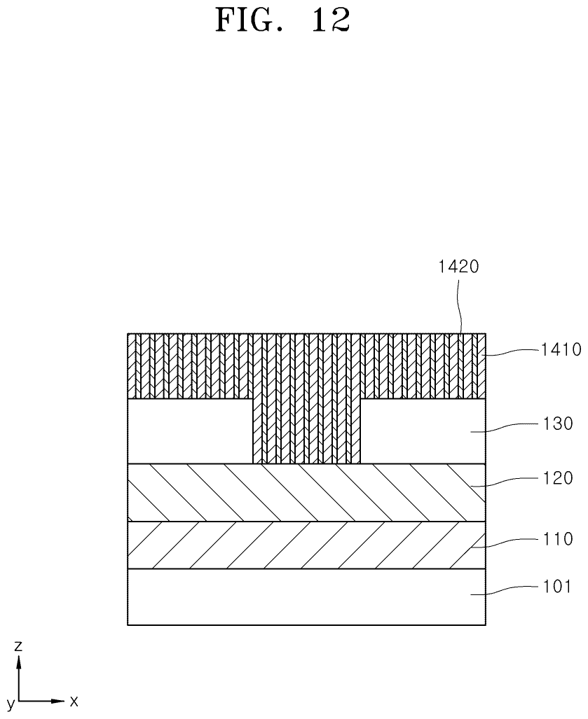

Referring to FIG. 12, the plurality of through holes HP2 of the polymer mold layer 1410 may be filled with a conductive material to form a plug material layer 1420. The conductive material may include, for example, a doped semiconductor material, metal, metal nitride, metal carbide, metal silicide, or metal oxide. As an example, the conductive material layer may include n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

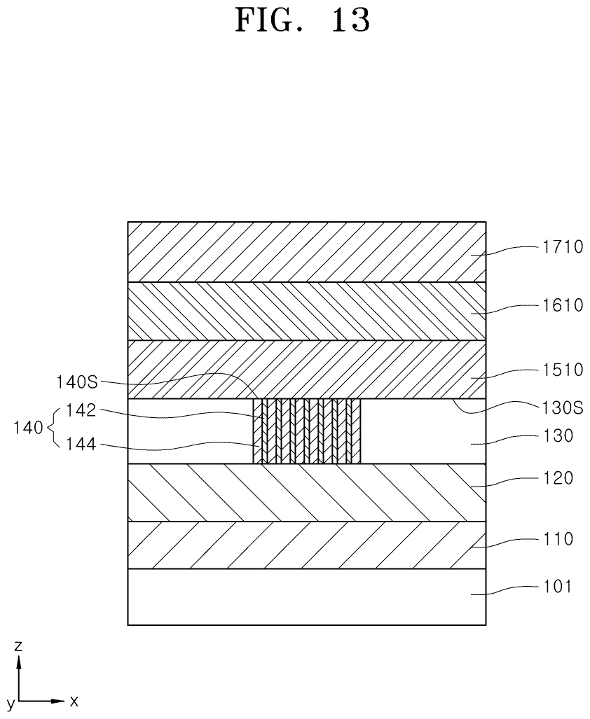

Referring to FIG. 13, the polymer mold layer 1410 in which the plug material layer 1420 is formed may be planarized to expose the second interlayer insulation layer 130 and form a plug electrode 140. An upper surface 140S of the plug electrode 140 and an upper surface of the second interlayer insulation layer 130 may be located at substantially the same level in the z-direction. The plug electrode 140 may include the plurality of conductive nanorods 142 formed from the plug material layer 1420 and a non-conductive mold layer 144 formed from the polymer mold layer 1410.

Subsequently, a resistance change material layer 1510, an oxygen vacancy reservoir 1610, and an upper electrode material layer 1710 may be sequentially formed on the second interlayer insulation layer 130. In an embodiment, the resistance change material layer 1510 may include a resistance change material whose electrical resistance state changes depending on the application of an external voltage. For example, the resistance change material may include metal oxide such as titanium oxide, aluminum oxide, nickel oxide, copper oxide, zirconium oxide, manganese oxide, hafnium oxide, tungsten oxide, tantalum oxide, niobium oxide, and iron oxide. The metal oxide may include oxygen vacancies. The resistance change material layer 1510 may be formed, for example, by an atomic layer deposition method, a chemical vapor deposition method, and the like. The oxygen vacancy reservoir material layer 1610 may have electrical conductivity. The oxygen vacancy reservoir material layer 1610 may include metal that is highly reactive with oxygen. For example, the metal may include tantalum (Ta), titanium (Ti), or a combination thereof. The oxygen vacancy reservoir material layer 1610 may be formed, for example, by an atomic layer deposition method, a chemical vapor deposition method, and the like.

The upper electrode material layer 1710 may include a conductive material. The conductive material may include, for example, a doped semiconductor material, metal, metal nitride, metal carbide, metal silicide, or metal oxide. As an example, the conductive material may include n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof. As an example, the upper electrode material layer 1710 may be formed by an atomic layer deposition method, a chemical vapor deposition method, and the like.

Referring to FIG. 14, the resistance change material layer 1510, the oxygen vacancy reservoir material layer 1610, and the upper electrode material layer 1710 may be patterned over the second interlayer insulation layer 130 to form a resistance change layer 150, an oxygen vacancy reservoir 160, and an upper electrode 170. The patterning process for the resistance change material layer 1510, the oxygen vacancy reservoir material layer 1610, and the upper electrode material layer 1710 may be performed such that the plug electrode 140 formed under the resistance change layer 150 is not exposed. That is, the patterning process for the resistance change material layer 1510, the oxygen vacancy reservoir material layer 1610, and the upper electrode material layer 1710 may be performed such that the plug electrode 140 is screened by or overlaps with the resistance change layer 150 in the z-direction.

Meanwhile, during the patterning process, an etching damage region 150R may be formed in an internal region of a predetermined width “a” from sidewalls 150SW of the resistance change layer 150. As an example, the width “a” may be less than 5 nm. In the etching damage region 150R, the resistance change material contained in the resistance change layer 150 may be in a non-homogeneous state. Accordingly, when an operating voltage such as a set voltage or reset voltage is applied between the plug electrode 140 and the upper electrode 170, leakage current could pass through the etching damage region 150R.

According to embodiments of the disclosure, the pattern edge 140E of the plug electrode 140 may be located at a predetermined distance from the pattern edge 150E (see FIG. 3) of the adjacent resistance change layer 150. As an example, the separation distance d2 between the pattern edges 140E and 150E may be 5 nm or more. Accordingly, the etching damage region 150R of the resistance change layer 150 and the plug electrode 140 may be configured not to contact each other in the z-direction. As a result, the leakage current that could occur through the etching damage region 150R may be prevented, thereby improving the electrical reliability of the semiconductor device.

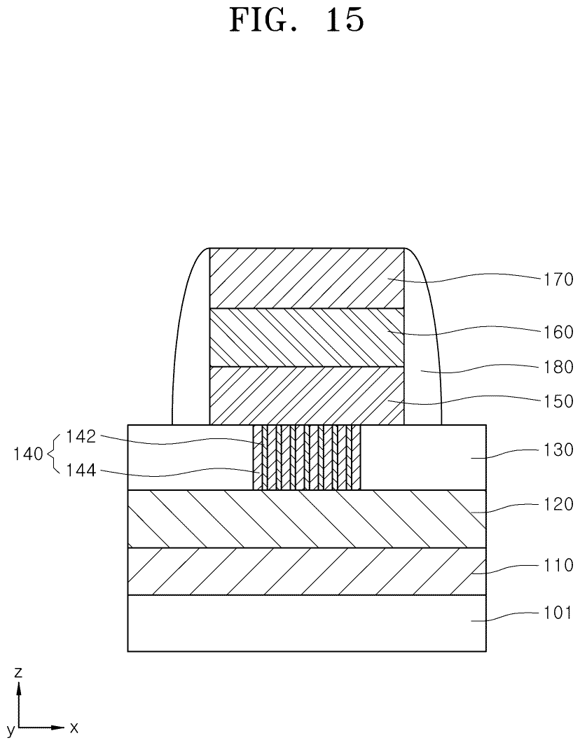

Referring to FIG. 15, a spacer 180 surrounding the side walls of the resistance change layer 150, the oxygen vacancy reservoir 160, and the upper electrode 170 may be formed on the second interlayer insulation layer 130. The spacer 180 may electrically insulate the resistance change layer 150, the oxygen vacancy reservoir 160, and the upper electrode 170 in the lateral direction, and may serve as a barrier layer that protects the resistance change layer 150, the oxygen vacancy storage layer 160, and the upper electrode 170 from material diffusion. The spacer 180 may include, for example, an insulative material, for example, oxide, nitride, oxynitride, or a combination of two or more thereof.

In some embodiments, in the process described with reference to FIG. 13, the process of forming the oxygen vacancy reservoir material layer 1610 may be omitted. In this case, the upper electrode material layer 1710 may be directly formed on the resistance change material layer 1510. The upper electrode material layer 1710 may include metal that is highly reactive with oxygen. For example, the upper electrode material layer 1710 may include tantalum (Ta), titanium (Ti), or a combination thereof. As an example, the upper electrode material layer 1710 may include tantalum nitride, titanium nitride, or a combination thereof. Subsequently, in the process described with reference to FIG. 14, the resistance change material layer 1510 and the upper electrode material layer 1710 may be patterned over the second interlayer insulation layer 130 to form the resistance change layer 150 and the upper electrode 170. Next, the spacer 180 may be formed on the sidewalls of the resistance change layer 150 and the upper electrode 170.

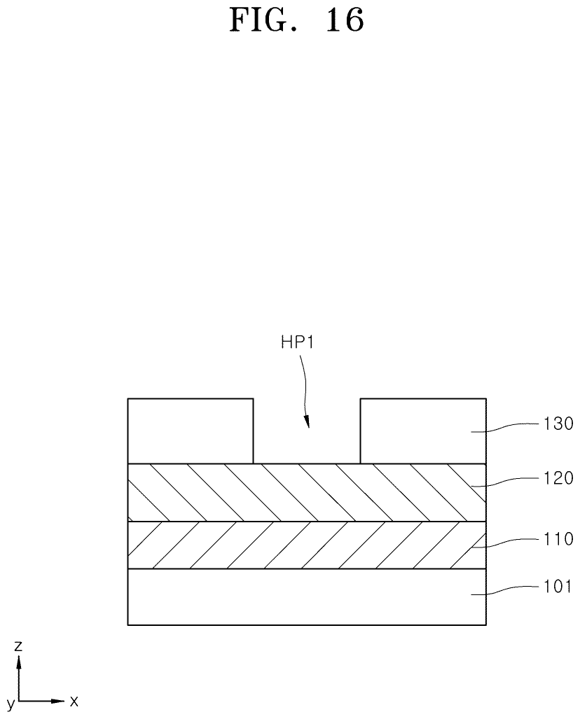

FIGS. 16, 17A, 17B, 18, and 19 are cross-sectional views schematically illustrating a method of manufacturing a semiconductor device according to another embodiment of the present disclosure. FIG. 17B is an enlarged perspective view of region A of FIG. 17A. The method of manufacturing may be applied to a semiconductor device 3 described above with reference to FIGS. 7A and 7B.

Referring to FIG. 16, processes substantially the same as the processes described with reference to FIGS. 8 and 9 may be performed to form a first interlayer insulation layer 110 and a lower electrode 120 sequentially disposed on a substrate 101. Subsequently, a second interlayer insulation layer 130 having a hole pattern HP1 may be formed on the lower electrode 120.

Referring to FIGS. 17A and 17B, an insulative metal-organic framework layer 2410 may be formed on the second interlayer insulation layer 130 to fill the hole pattern HP1 and may be disposed on the second interlayer insulation layer 130 outside the hole pattern HP1. The metal-organic framework layer 2410 may include a channel of a plurality of cavities V.

Referring to FIG. 17B, the metal-organic framework layer 2410 may be a thin film structure formed by sequentially stacking a plurality of two-dimensional metal-organic frameworks 2410a, 2410b, 2410c, and 2410d each having cavities V. The plurality of two-dimensional metal-organic frameworks 2410a, 2410b, 2410c, and 2410d may be stacked in the z-direction such that the cavities V of the plurality of two-dimensional metal-organic frameworks 2410a, 2410b, 2410c, and 2410d overlap each other. Accordingly, the metal-organic framework layer 2410 may include the channel formed of the cavities V extending in the z-direction. As an example, the metal-organic framework layer 2410 may be formed by an atomic layer deposition method, a chemical vapor deposition method, and the like.

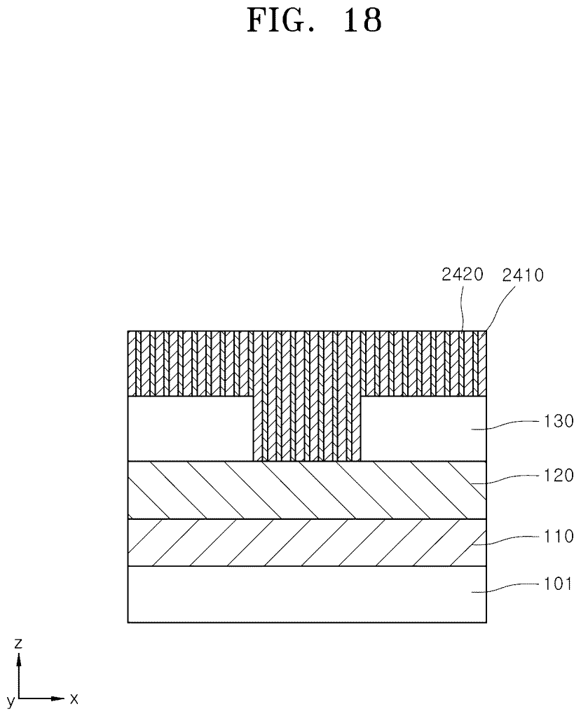

Referring to FIG. 18, the channels of the cavities V of the metal-organic framework layer 2410 may be filled with a conductive material to form a plug material layer 2420. The conductive material may include, for example, a doped semiconductor material, metal, metal nitride, metal carbide, metal silicide, or metal oxide. As an example, the conductive material layer may include n-type doped silicon (Si), platinum (Pt), gold (Au), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

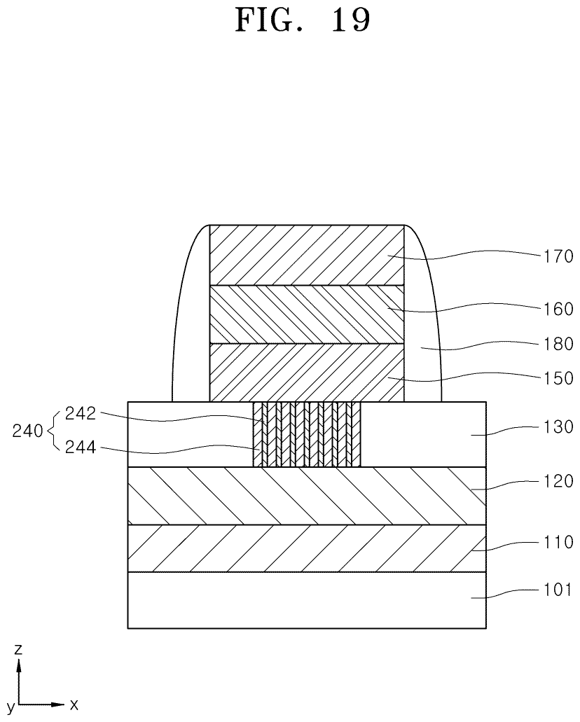

Referring to FIG. 19, the metal-organic framework layer 2410 in which the plug material layer 2420 is formed may be planarized to expose the second interlayer insulation layer 130 and form the plug electrode 240. The plug electrode 240 may include a plurality of conductive nanorods 242 formed from the plug material layer 2420 and a non-conductive mold layer 244 formed from the metal-organic framework layer 2410.

Subsequently, by performing substantially the same processes as the processes described with reference to FIGS. 14 and 15, the resistance change layer 150, the oxygen vacancy reservoir 160, and the upper electrode 170 may be disposed over the plug electrode 240. Next, the spacer 180 may be formed on the sidewalls of the resistance change layer 150, the oxygen vacancy reservoir 160, and the upper electrode 170.

As described above, semiconductor devices according to embodiments of the present disclosure may be applied to a resistive RAM device. In addition, semiconductor devices according to embodiments of the present disclosure may be applied to a memristor. The memristor is a compound word of memory and resistor, and may be a two-terminal device whose resistance state changes depending on an external electrical stimulation. The memristor can simultaneously implement memory functions and calculation functions through enhanced analog operation characteristics, and can simulate the role of a brain synapse. As an example, the semiconductor device can be applied to an oxide-based RAM (OxRAM) device, which generates a conductive path by oxygen vacancies.

Concepts have been disclosed in conjunction with some embodiments as described above. Those skilled in the art will appreciate that various modifications, additions, and substitutions are possible, without departing from the scope and spirit of the present disclosure. Accordingly, the embodiments disclosed in the present specification should be considered from not a restrictive standpoint but rather from an illustrative standpoint. The scope of the concepts is not limited to the above descriptions but defined by the accompanying claims, and all of distinctive features in the equivalent scope should be construed as being included in the concepts.

What is claimed is:

1. A semiconductor device comprising:
a lower electrode;
a plug electrode disposed over the lower electrode and including a plurality of conductive nanorods;
a resistance change layer disposed over the plug electrode; and
an upper electrode disposed over the resistance change layer.

2. The semiconductor device of claim 1, wherein the plug electrode comprises a non-conductive mold layer surrounding the plurality of conductive nanorods.

3. The semiconductor device of claim 2, wherein each of the plurality of conductive nanorods extends along a first direction that is substantially perpendicular to a surface of the lower electrode, and each of the plurality of conductive nanorods contacts the resistance change layer and the lower electrode.

4. The semiconductor device of claim 3, wherein each of the plurality of conductive nanorods is spaced apart from each other in a second direction perpendicular to the first direction.

5. The semiconductor device of claim 2, wherein the non-conductive mold layer comprises a polymer material or a metal-organic framework.

6. The semiconductor device of claim 1, wherein the plug electrode and the resistance change layer are disposed to contact each other.

7. The semiconductor device of claim 6, wherein in a plane at an interface of the plug electrode and the resistance change layer, a cross-sectional region of the plug electrode is located within a cross-sectional region of the resistance change layer.

8. The semiconductor device of claim 7, wherein in the plane, a pattern edge of the plug electrode is located at a distance of 5 nm or more from a pattern edge of an adjacent resistance change layer.

9. The semiconductor device of claim 6, wherein in a plane at an interface of the plug electrode and the resistance change layer, a cross-sectional region of the plurality of conductive nanorods is located within a cross-sectional region of the resistance change layer.

10. The semiconductor device of claim 9, wherein in the plane, the plurality of conductive nanorods is located at a distance of 5 nm or more from a pattern edge of the adjacent resistance change layer.

11. The semiconductor device of claim 7, wherein in the plane, the cross-section al region of the plug electrode is smaller than the cross-sectional region of the resistance change layer.

12. The semiconductor device of claim 1, wherein the resistance change layer further comprises a plurality of conductive filaments respectively connected to the plurality of conductive nanorods.

13. The semiconductor device of claim 12, wherein each of the plurality of conductive filaments is respectively connected to the plurality of conductive nanorods in a 1:1 correspondence.

14. The semiconductor device of claim 12, wherein in a contact portion of each of the conductive nanorods with each of the conductive filaments, a width of the conductive filament is less than ½ a pitch between conductive nanorods.

15. The semiconductor device of claim 1, wherein the resistance change layer further comprises conductive filaments connected in a 1:1 correspondence to some of the plurality of conductive nanorods.

16. The semiconductor device of claim 1,
wherein each of the plurality of conductive nanorods has a width of 1 nm to 5 nm, and
wherein each of the plurality of conductive nanorods is spaced apart from a nearest conductive nanorod at a distance of 1 nm to 50 nm.

17. The semiconductor device of claim 1, wherein the resistance change layer comprises a metal oxide including oxygen vacancies.

18. The semiconductor device of claim 1, further comprising an oxygen vacancy reservoir disposed between the resistance change layer and the upper electrode.

19. A method of manufacturing a semiconductor device, the method comprising:
forming a lower electrode over a substrate;
forming an interlayer insulation layer including a hole pattern over the lower electrode;
forming a plug electrode including a plurality of conductive nanorods and a non-conductive mold layer surrounding the plurality of conductive nanorods in the hole pattern;
sequentially forming a resistance change material layer and an upper electrode material layer over the interlayer insulation layer including the plug electrode; and
patterning the resistance change material layer and the upper electrode material layer over the interlayer insulation layer to form a resistance change layer that covers the plug electrode and an upper electrode.

20. The method of claim 19, wherein forming the plug electrode comprises:
forming a block copolymer layer filling the hole pattern and disposed over the interlayer insulation layer outside the hole pattern;
heat-treating the block copolymer layer to phase separate the block copolymer layer into a first polymer block in a form of a cylinder and a second polymer block surrounding the first polymer block;
selectively removing the first polymer block to form a polymer mold layer including a plurality of through holes; and
filing the plurality of through holes with a conductive material to form the conductive nanorods.

21. The method of claim 20, further comprising planarizing the polymer mold layer filled with the conductive material to expose the interlayer insulation layer.

22. The method of claim 19, wherein forming the plug electrode comprises:
forming an insulative metal-organic framework layer that fills the hole pattern, is disposed over the interlayer insulation layer outside the hole pattern, and has a channel of a plurality of cavities; and
filling the channel of the cavities of the insulative metal-organic framework layer with a conductive material to form the conductive nanorods.

23. The method of claim 19, wherein patterning the resistance change material layer and the upper electrode material layer comprises patterning the resistance change material layer and the upper electrode material layer to screen the plug electrode with the resistance change layer.

24. The method of claim 23, wherein patterning the resistance change material layer and the upper electrode material layer comprises patterning the resistance change material layer and the upper electrode material layer such that a pattern edge of the plug electrode is located at a distance of 5 nm or more from a pattern edge of an adjacent resistance change layer at a contact surface between the plug electrode and the resistance change layer.

25. The method of claim 19, further comprising:
forming an oxygen vacancy reservoir material layer between the resistance change material layer and the upper electrode material layer; and
patterning the oxygen vacancy reservoir material layer to form an oxygen vacancy reservoir between the resistance change layer and the upper electrode.
